(19) United States
(12) Patent Application Publication
(10) Pub. No.: US 2014/0209920 A1
(43) Pub. Date: Jul. 31, 2014

(54) High Electron Mobility Transistor Structure

(71) Applicant: TAIWAN SEMICONDUCTOR MANUFACTURING CO., LTD., Hsin-Chu (TW)

(72) Inventors: Po-Chun Liu, Hsinchu City (TW); Chi-Ming Chen, Zhubei City (TW); Chung-Yi Yu, Hsin-Chu (TW); Chia-Shiung Tsai, Hsin-Chu (TW)

(73) Assignee: Taiwan Semiconductor Manufacturing Co., Ltd., Hsin-Chu (TW)

(21) Appl. No.: 13/755,058

(22) Filed: Jan. 31, 2013

(51) Int. Cl. H01L 29/778; H01L 29/66

(52) U.S. Cl. CPC H01L 29/778; H01L 29/66431
USPC 257/76; 438/172

(57) ABSTRACT

The present disclosure relates to a channel layer of bi-layer of gallium nitride (GaN) within a HEMT. A first breakdown voltage layer of GaN is disposed beneath an active layer of the HEMT. A second breakdown voltage layer of GaN is disposed beneath the first breakdown voltage layer, wherein the first resistivity value is less than the second resistivity value. An increased resistivity of the second breakdown voltage layer results from an increased concentration of carbon dopants which increases the breakdown voltage in the second breakdown voltage layer, but can degrade the crystal structure. To alleviate this degradation, a crystal adaptation layer is disposed beneath the second breakdown voltage layer and configured to lattice-match to the second breakdown voltage layer of GaN. As a result, the HEMT achieves a high breakdown voltage without any associated degradation to the first breakdown voltage layer, wherein a channel of the HEMT resides.

### BACKGROUND

High electron mobility transistors (HEMTs) utilize a high-resistivity gallium nitride (GaN) channel layer under an active layer, such as AlGaN, to increase a breakdown voltage of the HEMTs. The GaN channel layer may also be doped with carbon or iron for increase resistivity and hence breakdown voltage. However, as the concentration of dopants is increased the crystal quality of the GaN channel layer is degraded, thus degrading mobility of a two-dimensional electron gas (2DEG) which forms a channel of the HEMT within the GaN channel layer in a vicinity of hetrojunction formed between the GaN channel layer and the active layer. The decreased mobility of the 2DEG degrades the performance of the HEMT.

### BRIEF DESCRIPTION OF THE DRAWINGS

FIG. 1 illustrates a cross-sectional view of a high electron mobility transistor (HEMT).

FIG. 2 illustrates a cross-sectional view of some embodiments of a HEMT comprising a breakdown voltage bi-layer of material disposed above a crystal adaptation layer.

FIGS. 3A-3R illustrate cross-sectional views of some embodiments of a breakdown voltage bi-layer of GaN disposed above a crystal adaptation layer fabrication within a transistor.

FIG. 4 illustrates some embodiments of a method to form a breakdown voltage bi-layer of GaN disposed above a crystal adaptation layer.

FIG. 5 illustrates some embodiments of a method to form a HEMT comprising a breakdown voltage bi-layer of GaN disposed above a crystal adaptation layer.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one of ordinary skill in the art, that one or more aspects described herein may be practiced with a lesser degree of these specific details. In other instances, known structures and devices are shown in block diagram form to facilitate understanding.

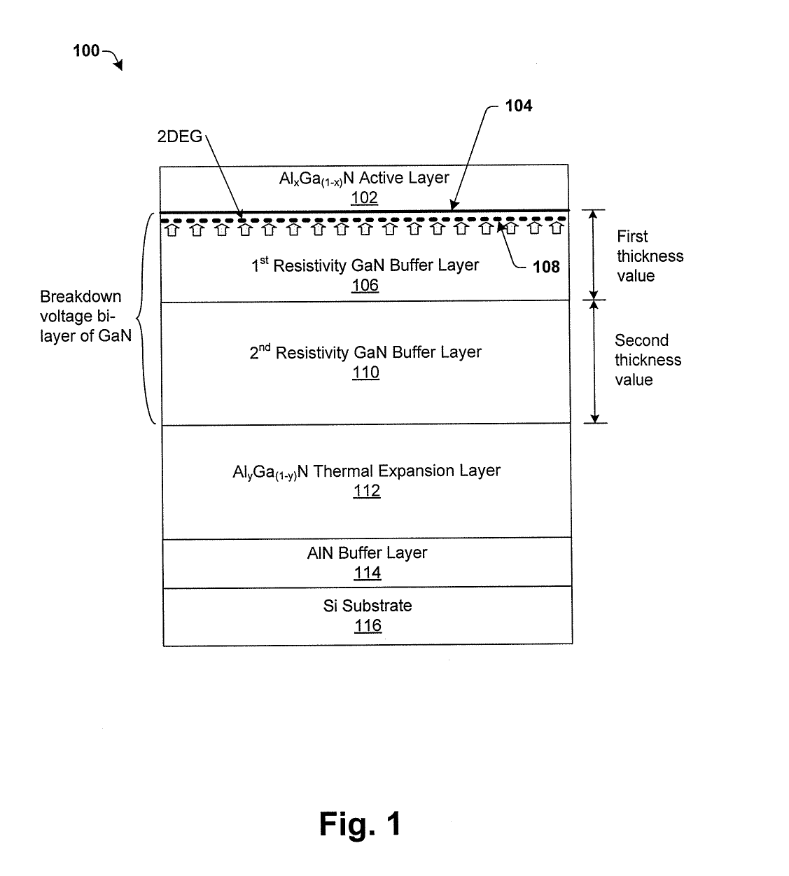

FIG. 1 illustrates a cross-sectional view of a high electron mobility transistor (HEMT) 100 comprising an active layer 102 of AlₓGa₍₁₋ₓ₎N which forms a heterojunction 104 at an interface to a first breakdown voltage layer 106 of gallium nitride (GaN) comprising a first resistivity value. The first breakdown voltage layer 106 is also referred as a channel layer 106. The first breakdown voltage layer 106 is disposed above a second breakdown voltage layer 110 of GaN comprising a second resistivity value, wherein the first resistivity value is less than the second resistivity value. The first breakdown voltage layer 106 and second breakdown voltage layer 110 combine to form a breakdown voltage bi-layer. The second breakdown voltage layer 110 is disposed above a thermal expansion layer 112 of Al_{y}Ga_{(1-y)}N, where 0<y<1. The thermal expansion layer 112 of Al_{y}Ga_{(1-y)}N is disposed above a buffer layer 114 of AlN. The buffer layer 114 of AlN is disposed above a Si substrate 116.

Electrons generated from the active layer 102 diffuse into the first breakdown voltage layer 106 (also channel layer 106) to form a two-dimensional electron gas (2DEG) 108, which comprises a channel of the HEMT within a vicinity of the heterojunction 104. A second carbon dopant concentration within the second breakdown voltage layer 110 is more than one order of magnitude greater than a first carbon dopant concentration within the first breakdown voltage layer 106, to achieve a second resistivity value that is substantially greater than the first resistivity value—allowing for an increased breakdown voltage within the second breakdown voltage layer 110 relative to the first breakdown voltage layer 106. However, heavily doped GaN is grown at a reduced pressure and temperature, degrading GaN crystal quality which in turn degrades electron mobility within the 2DEG, as well as a drain saturation current (I_{dsat}) and dynamic on-state resistance (Rₒₙ) of the HEMT 100.

Accordingly, the present disclosure relates to a breakdown voltage bi-layer of GaN is disposed above a crystal adaptation layer within a HEMT. A first breakdown voltage layer of gallium nitride (GaN) comprising a first resistivity value is disposed beneath an active layer of the HEMT. The first breakdown voltage layer is also referred as a channel layer. A second breakdown voltage layer of GaN comprising a second resistivity value is disposed beneath the first breakdown voltage layer, wherein the first resistivity value is less than the second resistivity value, resulting from an increased carbon dopant concentration within the second breakdown voltage layer relative to the first breakdown voltage layer. The increased resistivity resulting from carbon dopants increases the breakdown voltage in the second breakdown voltage layer, but can degrade the crystal structure of the first breakdown voltage layer due to defects at the surface of the second breakdown voltage layer, wherein the first breakdown voltage layer is epitaxially deposited. To alleviate this degradation, a crystal adaptation layer is disposed beneath the second breakdown voltage layer and configured to lattice-match to the second breakdown voltage layer of GaN—maintaining crystal quality of the layer of GaN which in turn maintains electron mobility within a 2DEG within the breakdown voltage bi-layer of GaN. As a result, the HEMT achieves a high breakdown voltage without any associated degradation to the first breakdown voltage layer, wherein the 2DEG of the HEMT resides. The breakdown voltage bi-layer of GaN obtains a high breakdown voltage without impacting performance of the HEMT, specifically the I_{dsat} and Rₒₙ, and achieves approximately 2× to 4× less defect density than some other approaches.

In at least one embodiment, the HEMT transistor includes a breakdown voltage bi-layer and an active layer (or donor-supply layer) having compounds made from the III-V groups in the periodic table of elements. However, the breakdown voltage bi-layer and the active layer are different from each other in composition.

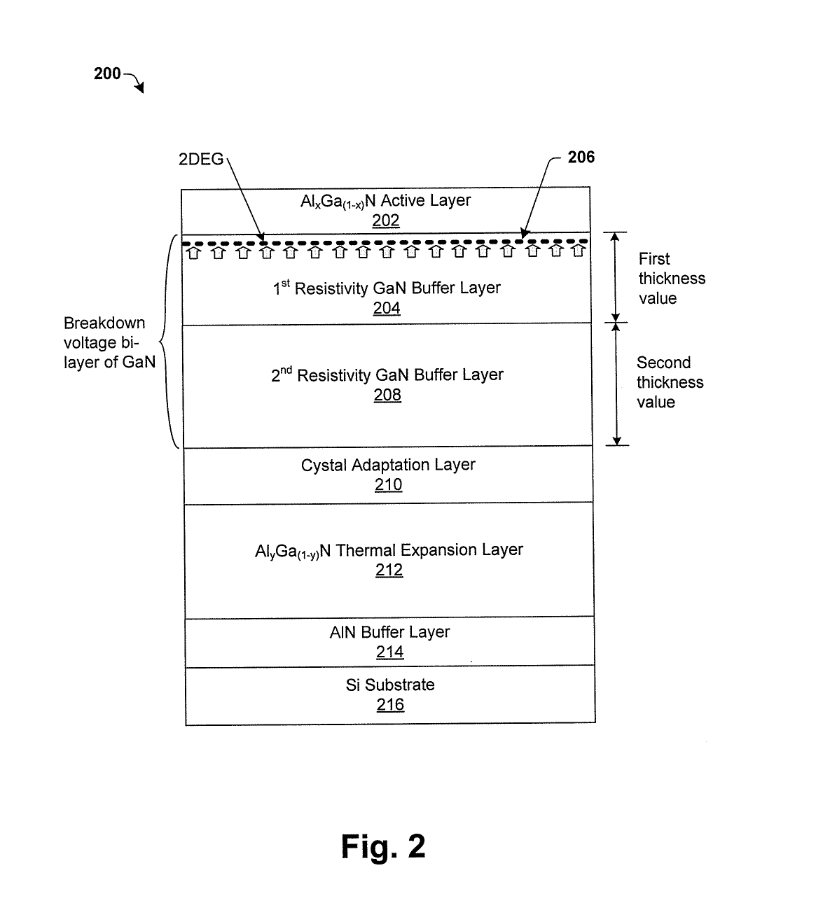

FIG. 2 illustrates a cross-sectional view of some embodiments of a HEMT 200 comprising a breakdown voltage bi-layer of material, the material comprising GaN disposed above a crystal adaptation layer 210. The breakdown voltage bi-layer further comprises a first breakdown voltage layer 204 (also channel layer 204) of GaN comprising a first resistivity value and containing a 2DEG 206, a second breakdown voltage layer 208 of GaN disposed beneath the first breakdown voltage layer 204 and comprising a second resistivity value. The first resistivity value is less than the second resistivity value. The crystal adaptation layer 210 is disposed beneath the second breakdown voltage layer 208 and configured to lattice-match to the second breakdown voltage layer 208. For the embodiments of FIG. 2, a third concentration of a third dopant within the crystal adaptation layer 210 is substantially less than a second concentration a second dopant within the second breakdown voltage layer 208, and a first concentration of a first dopant within the first breakdown voltage layer 204 is approximately equal to the third concentration of the third dopant. A thermal expansion layer 212 of Al_{y}Ga_{(1-y)}N is disposed beneath the crystal adaptation layer 210, wherein a second molar fraction y is less than approximately 1 and greater than approximately 0. A buffer layer 214 of AlN disposed beneath the thermal expansion layer and above a Si substrate 216.

For the embodiments of FIG. 2, a crystal orientation of Si substrate 216 is <111>, spawning <0001> c-plane orientations along interfaces of the buffer layer 214 of AlN, the thermal expansion layer 212 of Al_{y}Ga_{(1-y)}N, the crystal adaptation layer 210, the first breakdown voltage layer 204 of GaN, and the second breakdown voltage layer 208 of GaN. As such, the crystal adaptation layer 210 comprising GaN with a lattice-constant of approximately 0.57 nm is essentially equal to lattice constants of the first breakdown voltage layer 204 and second breakdown voltage layer 208, making it possible to epitaxially grow almost an arbitrarily thick first breakdown voltage layer 204 and second breakdown voltage layer 208 without loss of crystal quality due strain effects of substantially different lattice constants. The first dopant comprises carbon with a concentration less than approximately than 1e17 cm⁻³, the second dopant comprises carbon with a concentration higher than approximately 5e18 cm⁻³, and the third dopant comprises carbon with a concentration less than approximately than 1e17 cm⁻³. The first breakdown voltage layer comprises a first thickness of between approximately 0.25 microns (μm) and approximately 1 μm, the second breakdown voltage layer comprises a second thickness of between approximately 0.5 μm and approximately 4 μm, and the crystal adaptation layer comprises a third thickness of between approximately 0.2 μm and approximately 0.5 μm. An active layer of AlₓGa₍₁₋ₓ₎N is disposed over the first breakdown voltage layer 204, wherein the active layer of AlₓGa₍₁₋ₓ₎N comprises a fourth thickness of between approximately 0.02 μm and approximately 0.5 μm, and wherein a first molar fraction x is less than approximately 1 and greater than approximately 0.

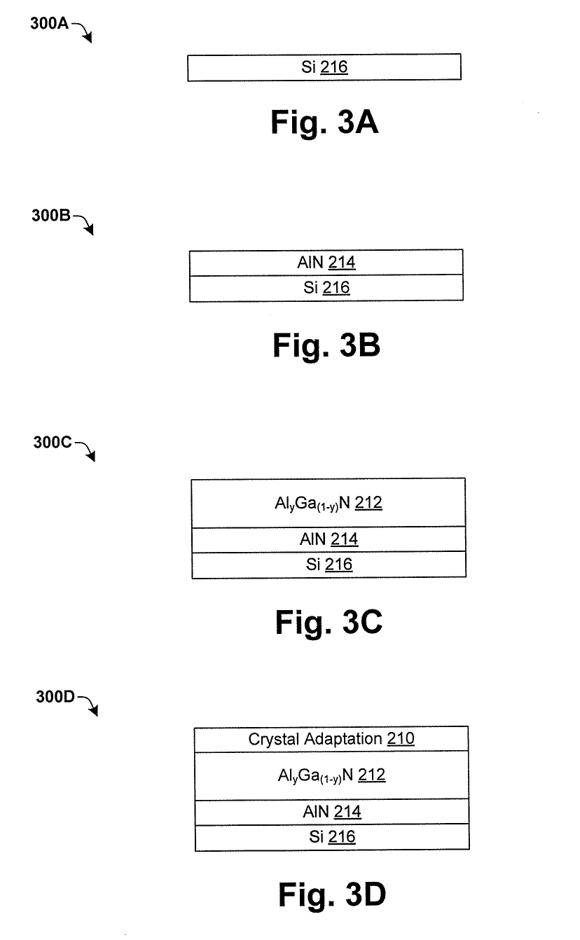

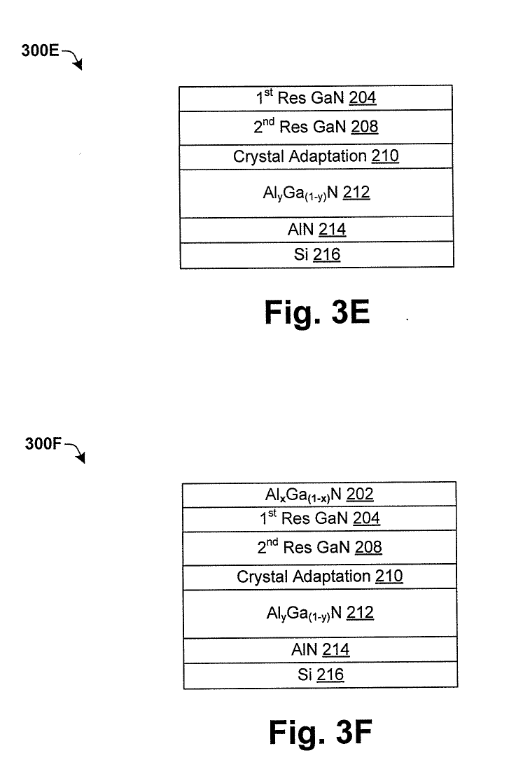

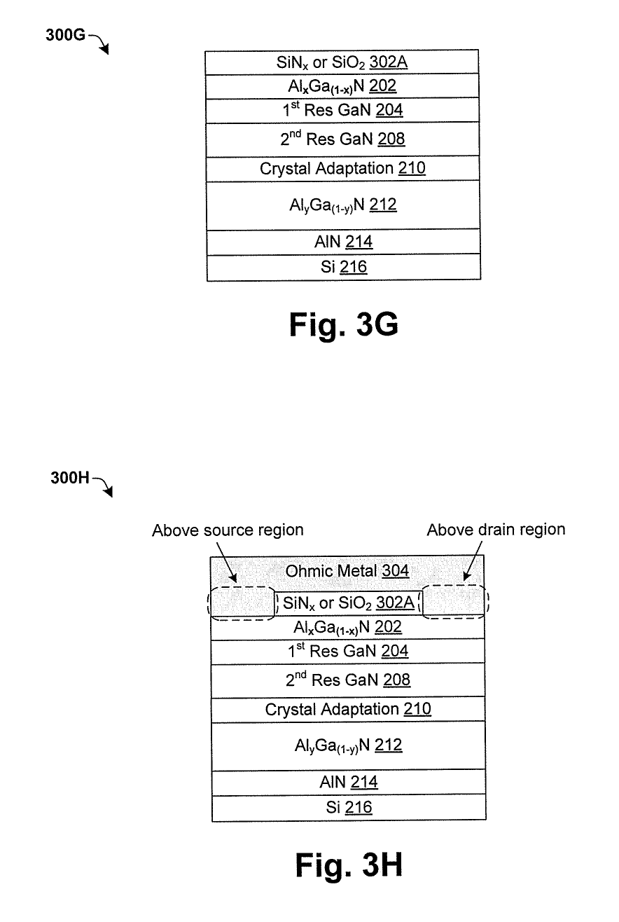

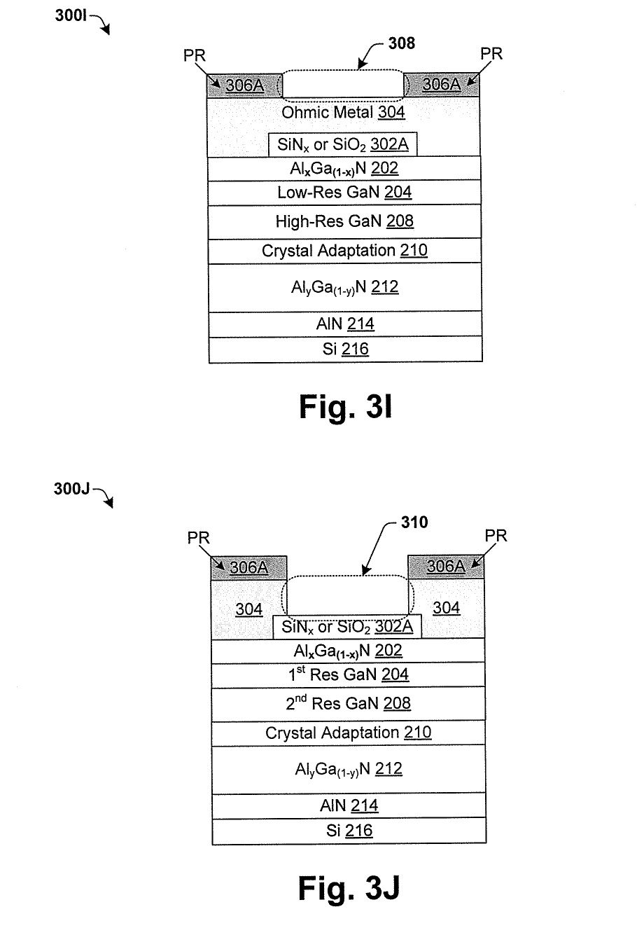

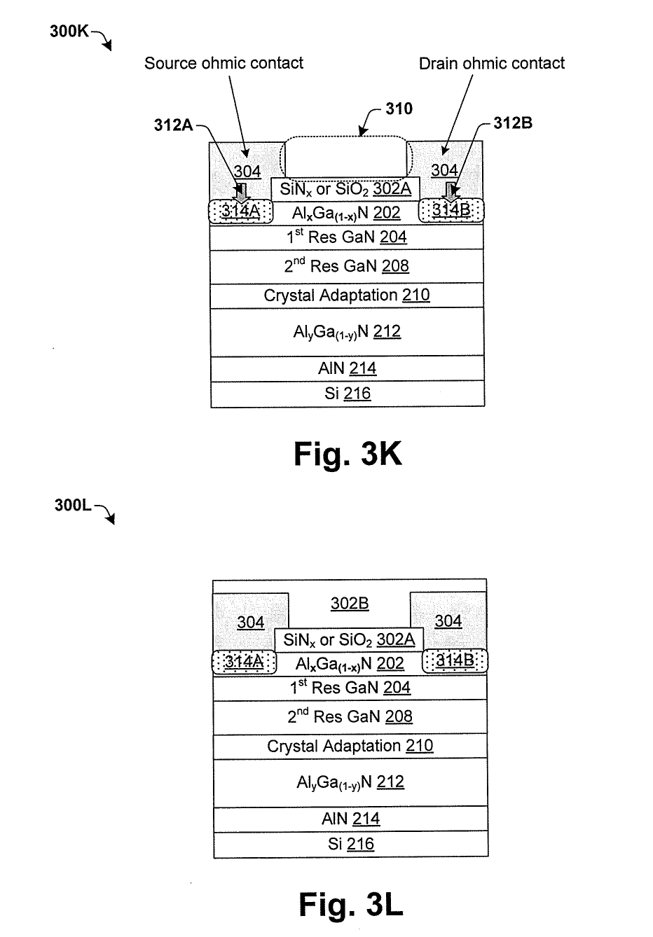

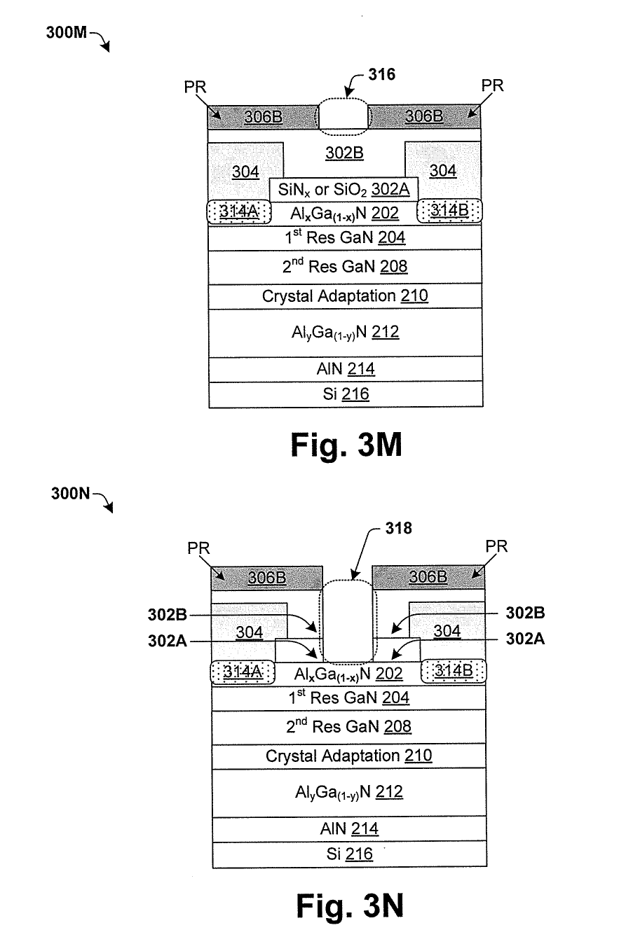

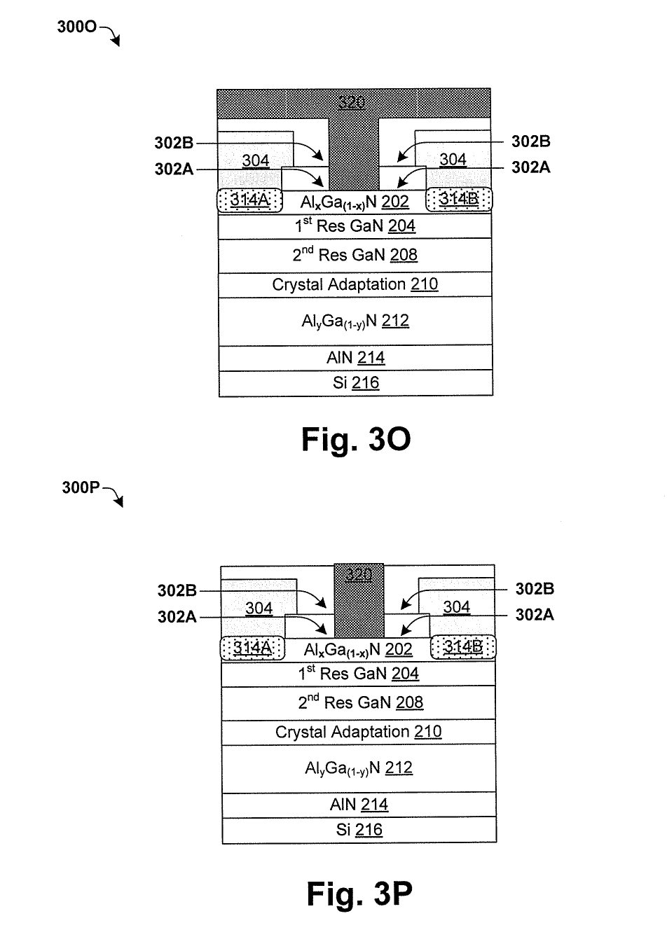

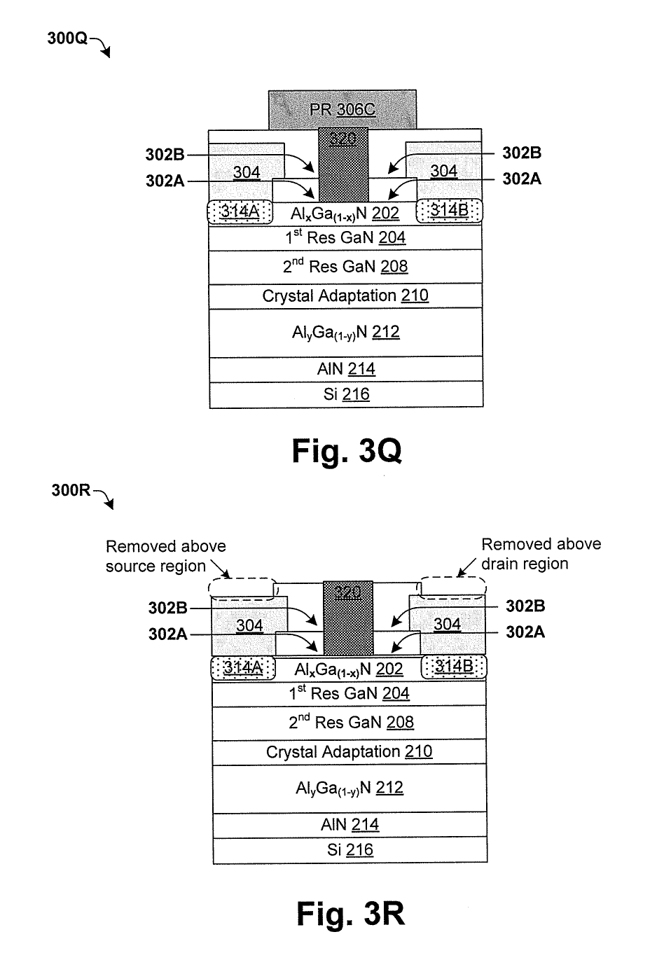

FIGS. 3A-3R illustrate cross-sectional views of some embodiments of a breakdown voltage bi-layer of GaN disposed above a crystal adaptation layer fabrication within a transistor. FIG. 3A illustrates a cross-sectional of a semiconductor workpiece comprising a Si substrate 216 further comprising a crystal orientation of <111>. FIG. 3B illustrates a semiconductor workpiece 300B comprising the semiconductor workpiece 300A of FIG. 3A, wherein a buffer layer 214 of AlN is disposed above a Si substrate 216. FIG. 3C illustrates a semiconductor workpiece 300C comprising the semiconductor workpiece 300B of FIG. 3B, wherein a thermal expansion layer 212 of Al_{y}Ga_{(1-y)}N is disposed above the buffer layer 214 of AlN, wherein a second molar fraction y is less than approximately 1 and greater than approximately 0. FIG. 3D illustrates a semiconductor workpiece 300D comprising the semiconductor workpiece 300C of FIG. 3C, wherein a crystal adaptation layer 210 is disposed above the thermal expansion layer 212 of Al_{y}Ga_{(1-y)}N. In some embodiments, the crystal adaptation layer 210 comprises a compound made from the III-V groups in the periodic table of elements, such as GaN comprising a third carbon dopant concentration of less than approximately than 1e17 cm⁻³. FIG. 3E illustrates a semiconductor workpiece 300E comprising the semiconductor workpiece 300D of FIG. 3D, wherein a breakdown voltage bi-layer of GaN is disposed above the crystal adaptation layer 210. The breakdown voltage bi-layer of GaN further comprises a first breakdown voltage layer 204 of GaN comprising a first resistivity value and a first carbon dopant concentration of less than approximately than 1e17 cm⁻³, and a second breakdown voltage layer 208 of GaN disposed beneath the first breakdown voltage layer and comprising a second resistivity value and second carbon dopant concentration larger than approximately than 5e18 cm⁻³, wherein the first resistivity value is less than the second resistivity value. In some embodiments, the crystal adaptation layer 210 comprises GaN and is disposed beneath the second breakdown voltage layer 208 of GaN, and is configured to lattice-match to the second breakdown voltage layer 208 of GaN. FIG. 3F illustrates a semiconductor workpiece 300F comprising the semiconductor workpiece 300E of FIG. 3E, wherein an active layer 202 of AlₓGa₍₁₋ₓ₎N is disposed over the first breakdown voltage layer, wherein the active layer of AlₓGa₍₁₋ₓ₎N comprises a first molar fraction x is less than approximately 1 and greater than approximately 0.

FIG. 3G illustrates a semiconductor workpiece 300G comprising the semiconductor workpiece 300F of FIG. 3F, wherein a first isolation layer 302A has been added above the active layer 202 of AlₓGa₍₁₋ₓ₎N. The first isolation layer 302A comprises SiNₓ or SiO₂, wherein x is the first molar fraction. FIG. 3H illustrates a semiconductor workpiece 300H comprising the semiconductor workpiece 300G of FIG. 3G, wherein portions of the first isolation layer 302A have been removed above a source region and a drain region, and wherein an ohmic metallization layer 304 has been added above the first isolation layer 302A, source region, and drain region, to form a source ohmic contact and a drain ohmic contact to the HEMT. In some embodiments, the ohmic metallization layer 304 comprises Ti/Al/Ti or Ti/Al/Ti/TiN. FIG. 3I illustrates a semiconductor workpiece 300I comprising the semiconductor workpiece 300H of FIG. 3H, wherein a first layer of photoresist 306A has been disposed above the ohmic metallization layer 304, exposed, and developed through optical lithography to create an first opening 308 in the first layer of photoresist 306A. FIG. 3J illustrates a semiconductor workpiece 300J comprising the semiconductor workpiece 300I of FIG. 3I, wherein the ohmic metallization layer 304 has been etched away beneath the first opening 308 to create a first recess 310 within the ohmic metallization layer 304. FIG. 3K illustrates a semiconductor workpiece 300K comprising the semiconductor workpiece 300J of FIG. 3J, wherein electrons tunnel from the ohmic metallization layer 304 into the active layer 202 of AlₓGa₍₁₋ₓ₎N through a source tunneling junction 312A between the ohmic metallization layer 304 and a source region 314A, and a drain tunneling junction 312B between the ohmic metallization layer 304 and a drain region 314B. Electrons within the active layer 202 of AlₓGa₍₁₋ₓ₎N also diffuse into the first isolation layer 302A, and accumulate to form the 2DEG 206 of FIG. 2. FIG. 3L illustrates a semiconductor workpiece 300L comprising the semiconductor workpiece 300K of FIG. 3K, wherein a second isolation layer 302B been added above the first isolation layer 302A and the ohmic metallization layer 304. The second isolation layer 302B also comprises SiNₓ or SiO₂, wherein x is the first molar fraction.

FIG. 3M illustrates a semiconductor workpiece 300M comprising the semiconductor workpiece 300L of FIG. 3L, wherein a second layer of photoresist 306B has been disposed above the second isolation layer 302B, exposed, and developed through optical lithography to create an second opening 316 in the second layer of photoresist 306B. FIG. 3N illustrates a semiconductor workpiece 300N comprising the semiconductor workpiece 300M of FIG. 3M, wherein portions of the second isolation layer 302B and the first isolation layer 302A have been etched away beneath the second opening 316 to create a second recess 318 over a gate region. FIG. 3O illustrates a semiconductor workpiece 300O comprising the semiconductor workpiece 300N of FIG. 3N, wherein the second recess 318 has been filled with a gate material 320 which extends over a surface of the second isolation layer 302B. In some embodiments, the gate material 320 comprises TiN or WN. FIG. 3P illustrates a semiconductor workpiece 300P comprising the semiconductor workpiece 300O of FIG. 3O, wherein the gate material 320 over the surface of the second isolation layer 302B has been removed. FIG. 3Q illustrates a semiconductor workpiece 300Q comprising the semiconductor workpiece 300P of FIG. 3P, wherein a third layer of photoresist 306C has been disposed, exposed, and developed through optical lithography to remove the third layer of photoresist 306C above the source region 314A and a drain region 314B. FIG. 3R illustrates a semiconductor workpiece 300R comprising the semiconductor workpiece 300Q of FIG. 3Q, wherein portions of the second isolation layer 302B have been etched away above the source region 314A and a drain region 314B to allow for a contact to the source region 314A and a drain region 314B through the ohmic metallization layer 304, resulting in a HEMT transistor.

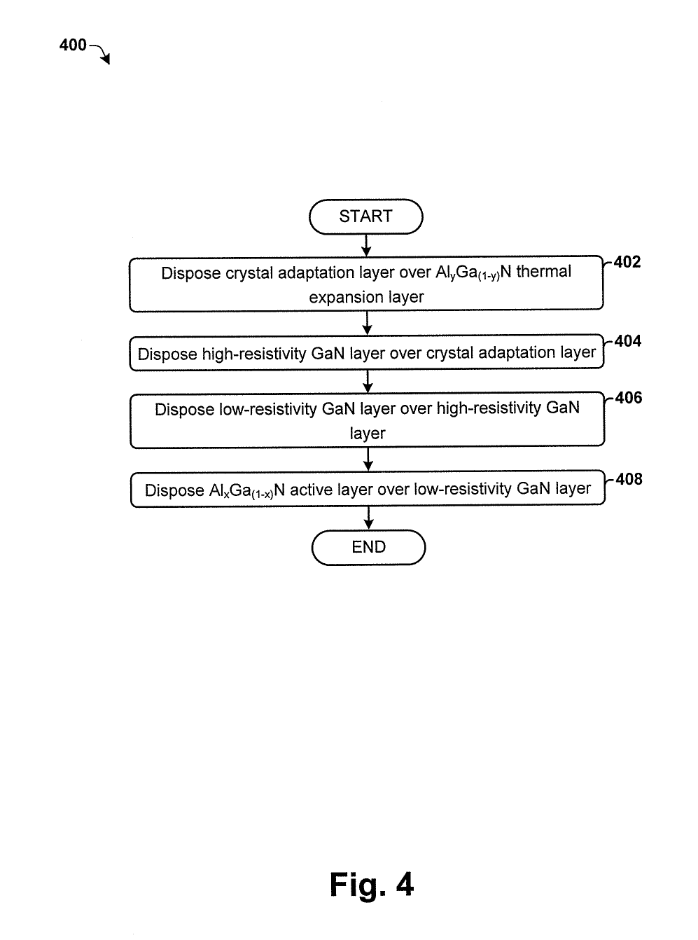

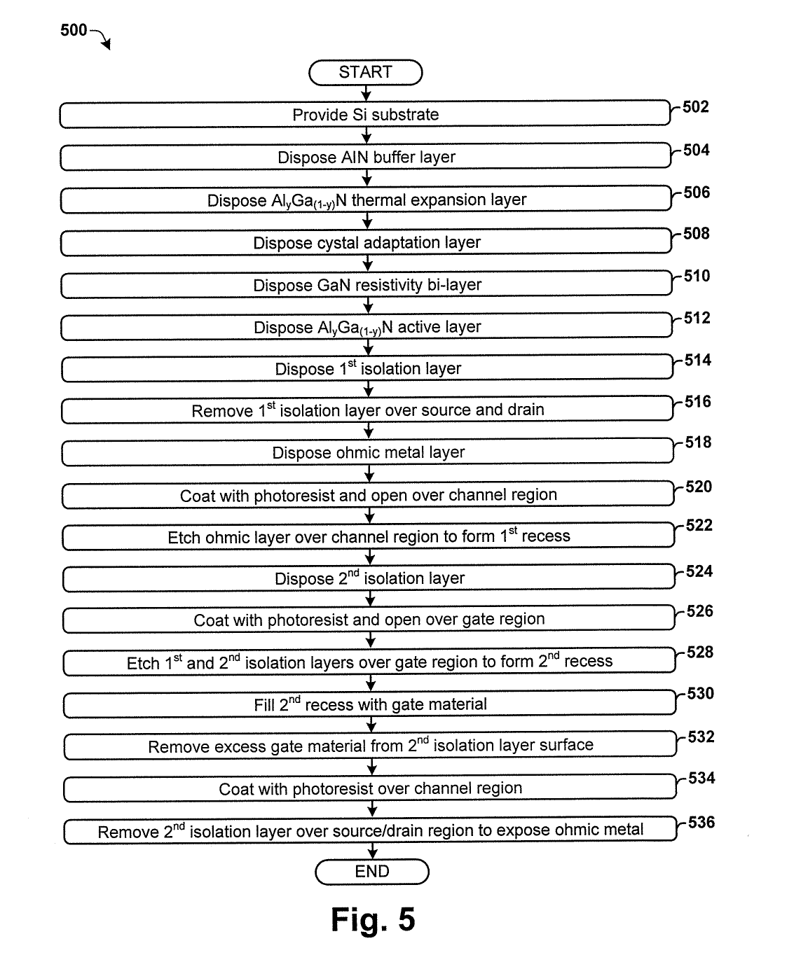

FIGS. 4-5 illustrate some embodiments of methods 400 and 500 to form a breakdown voltage bi-layer of GaN disposed above a crystal adaptation layer, and to form a HEMT comprising a breakdown voltage bi-layer of GaN disposed above a crystal adaptation layer, respectively. While methods 400 and 500 are illustrated and described as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

FIG. 4 illustrates some embodiments of a method 400 to form a breakdown voltage bi-layer of GaN disposed above a crystal adaptation layer.

At 402 a crystal adaptation layer is disposed above a thermal expansion layer of Al_{y}Ga_{(1-y)}N, wherein a second molar fraction y is less than approximately 1 and greater than approximately 0. The thermal expansion layer of Al_{y}Ga_{(1-y)}N is in turn disposed above a buffer layer of AlN, which is in turn disposed above a Si substrate. In some embodiments, a crystal orientation of the buffer layer of AlN and the thermal expansion layer of Al_{y}Ga_{(1-y)}N comprise a <0001> c-plane orientation, resulting from a Si substrate crystal orientation of <111>. In some embodiments, disposing the crystal adaptation layer comprises MOCVD or MBE, and further comprises carbon-doping the crystal adaptation layer with a third dopant concentration less than approximately than 1e17 cm⁻³, surrounding the semiconductor workpiece with an NH₃ gas comprising a NH₃N group ratio of greater than approximately 1,000 at a pressure of higher than approximately 500 mbar, resulting in the crystal adaptation layer comprising a third thickness of between approximately 0.2 μm and approximately 0.5 μm.

At 404 a second breakdown voltage layer comprising a second carbon dopant concentration is disposed above the crystal adaptation layer though metal organic chemical vapor deposition (MOVCD) or molecular beam epitaxy (MBE). The crystal adaptation layer is configured to lattice-match to the second breakdown voltage layer. In some embodiments, the second breakdown voltage layer comprises GaN, and disposing the second breakdown voltage layer further comprises carbon-doping the second breakdown voltage layer with the second dopant concentration larger than approximately than 5e18 cm⁻³, surrounding the device with an ammonia (NH₃) gas comprising a NH₃N group ratio of less than approximately 500 at a pressure of less than approximately 100 millibar (mbar), and an ambient temperature of less than approximately 1100° C., resulting in the second breakdown voltage layer comprising a second thickness of between approximately 0.5 microns (μm) and approximately 4 μm with a <0001> c-plane orientation.

At 406 a first breakdown voltage layer comprising a first carbon dopant concentration that is substantially less than a second carbon dopant concentration is disposed above the second breakdown voltage layer though MOVCD or MBE. In some embodiments, the first breakdown voltage layer comprises GaN, and disposing the first breakdown voltage layer further comprises carbon-doping the first breakdown voltage layer with the first dopant concentration less than approximately than 1e17 cm⁻³, and surrounding the device with an NH₃ gas comprising a NH₃N group ratio of less than approximately 1,000 at a pressure of higher than approximately 200 mbar, resulting in the first breakdown voltage layer comprising a first thickness of between approximately 0.25 μm and approximately 1 μm with a <0001> c-plane orientation.

At 408 an active layer of AlₓGa₍₁₋ₓ₎N is disposed over the first breakdown voltage layer comprising a fourth thickness of between approximately 0.02 μm and approximately 0.5 μm, wherein a first molar fraction x is less than approximately 0.4 and greater than approximately 0.15.

FIG. 5 illustrates some embodiments of a method 500 to form a HEMT comprising a breakdown voltage bi-layer of GaN disposed above a crystal adaptation layer.

At 502 a Si substrate comprising a crystal orientation of <111> is provided.

At 504 a buffer layer of AlN is disposed above a Si substrate via MOCVD or MBE, wherein the buffer layer comprises a <0001> c-plane orientation.

At 506 a thermal expansion layer of Al_{y}Ga_{(1-y)}N is disposed above the buffer layer of AlN via MOCVD or MBE, wherein the thermal expansion layer comprises a <0001> c-plane orientation.

At 508 a crystal adaptation layer is disposed above a thermal expansion layer of Al_{y}Ga_{(1-y)}N via MOCVD or MBE, wherein the crystal adaptation layer comprises a <0001> c-plane orientation.

At 510 a breakdown voltage bi-layer of GaN is disposed above and lattice-match to the crystal adaptation layer via MOCVD or MBE. The breakdown voltage bi-layer of GaN further comprises a first breakdown voltage layer of GaN comprising a first resistivity value and a first carbon dopant concentration, and a second breakdown voltage layer of GaN disposed beneath the first breakdown voltage layer and comprising a second resistivity value and second carbon dopant concentration, which is more than an order of magnitude larger than the first carbon dopant concentration.

At 512 an active layer of AlₓGa₍₁₋ₓ₎N is disposed over the first breakdown voltage layer through MOCVD or MBVE, wherein a first molar fraction x is less than 0.4 and greater than 0.15.

At 514 a first isolation layer comprising SiNₓ or SiO₂ is disposed above the active layer of AlₓGa₍₁₋ₓ₎N through MOVCD or MBE.

At 516 portions of the first isolation layer are removed above a source region and a drain region through a photomask patterning process comprising optical lithography and subsequent etch step (e.g., a wet etch, dry etch, chemical etch, plasma etch, a combination thereof, etc.).

At 518 an ohmic metallization layer is disposed above the first isolation layer, source region, and drain region through sputtering, a thermal coating technique, an e-beam evaporator, etc. In some embodiments, the ohmic metallization layer comprises Ti/Al/Ti or Ti/AIM/TiN

At 520 a first layer of photoresist is disposed above the ohmic metallization layer through a spin-coating technique. The first layer of photoresist is exposed and developed through optical lithography to create a first opening the first layer of photoresist above a channel region of the HEMT

At 522 the ohmic metallization layer is etched away beneath the first opening to create a first recess within the ohmic metallization layer.

At 524 a second isolation layer is disposed above the first isolation layer and the ohmic metallization layer. The second isolation layer also comprises SiNₓ or SiO₂, wherein x is the first molar fraction, and is disposed through low pressure chemical vapor deposition (LPCVD) or plasma enhanced chemical vapor deposition (PECVD).

At 526 a second layer of photoresist is spin-coated above the second isolation layer, and exposed and developed through optical lithography to create a second opening in the second layer of photoresist.

At 528 portions of the second isolation layer and the first isolation layer are etched away beneath the second opening to create a second recess over the channel region of the HEMT.

At 530 the second recess is been filled with a gate material which extends over a surface of the second isolation layer. In some embodiments the gate material comprises TiN or WN.

At 532 excess gate material is removed over the surface of the second isolation layer through a photomask patterning process comprising optical lithography and subsequent etch step.

At 534 a third layer of photoresist is spin-coated above the HEMT, patterned, exposed, and developed through optical lithography to remove the third layer of photoresist above the source/drain regions of the HEMT.

At 536 the portions of the second isolation layer are etched away above the source/drain regions to allow for a contact to the source/drain regions through the ohmic metallization layer, resulting in the HEMT 200 of FIG. 2.

It will also be appreciated that equivalent alterations and/or modifications may occur to one of ordinary skill in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein; such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein.

Therefore, the present disclosure relates to a breakdown voltage bi-layer of GaN is disposed above a crystal adaptation layer within a HEMT. A first breakdown voltage layer of GaN comprising a first resistivity value is disposed beneath an active layer of the HEMT. A second breakdown voltage layer of GaN comprising a second resistivity value is disposed beneath the first breakdown voltage layer, wherein the first resistivity value is less than the second resistivity value, resulting from an increased carbon dopant concentration within the second breakdown voltage layer relative to the first breakdown voltage layer. A crystal adaptation layer is disposed beneath the second breakdown voltage layer and configured to lattice-match to the second breakdown voltage layer of GaN. As a result, the HEMT achieves a high breakdown voltage without any associated degradation to the first breakdown voltage layer, wherein a channel of the HEMT resides. The channel bi-layer of GaN obtains a high breakdown voltage without impacting performance of the HEMT, specifically the I_{dsat} and Rₒₙ, and achieves approximately 2× to 4× less defect density than some prior art approaches.

1-8. (canceled)

9. A high electron mobility transistor (HEMT), comprising:
a first breakdown voltage layer comprising a first resistivity value, wherein the first breakdown voltage layer exhibits a first lattice-constant and is doped with a first dopant at a first doping concentration;
a second breakdown voltage layer disposed beneath the first breakdown voltage layer and comprising a second resistivity value that is greater than, the first resistivity value, wherein the second breakdown voltage layer exhibits a second lattice-constant that is substantially equal to the first lattice-constant and is doped with a second dopant at a second doping concentration that is greater than the first doping concentration; and
a crystal adaptation layer disposed beneath the second breakdown voltage layer, wherein the crystal adaptation layer exhibits a third lattice-constant which is substantially equal to each of the first and second lattice-constants; and wherein the crystal adaptation layer is doped with a third dopant at a third doping concentration that is approximately equal to the first doping concentration.

10. The HEMT of claim 9, further comprising:
a thermal expansion layer of Al_{y}Ga_{(1-y)}N disposed beneath the crystal adaptation layer, wherein a thermal expansion layer molar fraction y is less than 1 and greater than 0; and
a buffer layer of AlN disposed beneath the thermal expansion layer and above a Si substrate.

11. The HEMT of claim 10, wherein:
the first dopant comprises carbon and the first doping concentration is less than approximately than 1e17 cm⁻³;
the second dopant comprises carbon and the second doping concentration is larger than approximately 5e18 cm⁻³; and
the third dopant comprises carbon and the third doping concentration is less than approximately than 1e17 cm⁻³.

12. The HEMT of claim 11, wherein:
the first breakdown voltage layer comprises gallium nitride (GaN) and has a first thickness of between approximately 0.25 microns (μm) and approximately 1 μm;
the second breakdown voltage layer comprises GaN and has a second thickness of between approximately 0.5 μm and approximately 4 μm; and
the crystal adaptation layer comprises a third thickness of between approximately 0.2 μm and approximately 0.5 μm.

13. The HEMT of claim 10, further comprising an active layer of AlₓGa₍₁₋ₓ₎N disposed over the first breakdown voltage layer, wherein the active layer of AlₓGa₍₁₋ₓ₎N comprises a fourth thickness of between approximately 0.02 μm and approximately 0.5 μm, and wherein an active layer molar fraction x is less than approximately 0.4 and greater than approximately 0.15.

14. A transistor, comprising:
a first breakdown voltage layer of gallium nitride (GaN) comprising a first resistivity value and a first carbon dopant concentration of less than approximately than 1e17 cm⁻³; and
a second breakdown voltage layer of GaN disposed beneath the first breakdown voltage layer and comprising a second resistivity value and a second carbon dopant concentration larger than approximately than 5e18 cm⁻³, wherein the first resistivity value is less than the second resistivity value; and
a crystal adaptation layer disposed beneath the second breakdown voltage layer and configured to lattice-match to the second breakdown voltage layer, wherein the crystal adaptation layer comprises a first lattice-constant which is essentially equal to a second lattice-constant of the first breakdown voltage layer and a third lattice-constant of the second breakdown voltage layer, and wherein a third carbon dopant concentration within the crystal adaptation layer is less than approximately than 1e17 cm⁻³.

15. The transistor of claim 14, wherein the crystal adaptation layer comprises GaN.

16. The transistor of claim 14, further comprising an active layer of AlₓGa₍₁₋ₓ₎N disposed over the first breakdown voltage layer, wherein the active layer of AlₓGa₍₁₋ₓ₎N comprises an active layer first molar fraction x is less than approximately 0.4 and greater than approximately 0.15.

17. The transistor of claim 16, further comprising:
a source ohmic contact connecting to the active layer disposed over a source region of the transistor;
a drain ohmic contact connecting to the active layer disposed over a drain region of the transistor;
an isolation layer disposed over the active layer between the source ohmic contact and the drain ohmic contact; and
a gate material disposed within the isolation layer over a channel region and connecting to the active layer.

18. The transistor of claim 17, wherein:
the source ohmic contact and drain ohmic contact comprise Ti/Al/Ti or Ti/Al/Ti/TiN; and
the gate material comprises TiN or WN.

19. The transistor of claim 18, further comprising:
a thermal expansion layer of Al_{y}Ga_{(1-y)}N disposed beneath the crystal adaptation layer, wherein a crystal adaptation layer molar fraction y is less than 1 and greater than 0; and
a buffer layer of AlN disposed beneath the thermal expansion layer and above a Si substrate.

20. The transistor of claim 18, wherein:
the first breakdown voltage layer of GaN comprises a first thickness of between approximately 0.25 microns (μm) and approximately 1 μm;
the second breakdown voltage layer of GaN comprises a second thickness of between approximately 0.5 μm and approximately 4 μm;
the crystal adaptation layer comprises a third thickness of between approximately 0.2 μm and approximately 0.5 μm.

21. A transistor, comprising:
a first breakdown voltage layer comprising a first carbon dopant concentration, which forms a channel region of the transistor;
a second breakdown voltage layer formed beneath the first breakdown voltage layer, and comprising a second carbon dopant concentration that is about an order of magnitude greater than the first carbon dopant concentration; and
a crystal adaptation layer formed beneath the second breakdown voltage layer, configured to lattice-match to the second breakdown voltage layer, and comprising a third carbon dopant concentration that is about an order of magnitude less than the second carbon dopant concentration.

22. The transistor of claim 21, wherein the first breakdown voltage layer is formed below an active layer, such that electrons diffuse from the active layer into the first breakdown voltage layer to form the channel region, which comprises a two-dimensional electron gas (2DEG) formed between source and drain regions of the transistor.

23. The transistor of claim 22, further comprising:
a source contact connecting to the active layer disposed over the source region;
a drain contact connecting to the active layer disposed over the drain region;
an isolation layer disposed over the active layer between the source and drain contacts; and
a gate disposed within the isolation layer over the channel region, and connecting to the active layer.

24. The transistor of claim 22, wherein the active layer comprises AlₓGa₍₁₋ₓ₎N, with an active layer molar fraction x that is less than approximately 0.4 and greater than approximately 0.15.

25. The transistor of claim 24, wherein the active layer of AlₓGa₍₁₋ₓ₎N has a fourth thickness of between approximately 0.02 μm and approximately 0.5 μm.

26. The transistor of claim 21, wherein the first and third carbon dopant concentrations are less than about 1e17 cm⁻³, and wherein the second carbon dopant concentration is greater than about 5e18 cm⁻³.

27. The transistor of claim 21, wherein the first and second breakdown voltage layers comprises gallium nitride (GaN).

28. The transistor of claim 21, wherein the first breakdown voltage layer has a first thickness of between approximately 0.25 microns (μm) and approximately 1 μm;
the second breakdown voltage layer has a second thickness of between approximately 0.5 μm and approximately 4 μm; and
the crystal adaptation layer has a third thickness of between approximately 0.2 μm and approximately 0.5 μm.
